(19) United States
(12) Patent Application Publication
(10) Pub. No.: US 2014/0065394 A1
(43) Pub. Date: Mar. 6, 2014

(54) MULTI-LAYER COATING AND METHOD FOR FORMING THE SAME

(71) Applicant: HYUNDAI MOTOR COMPANY, Seoul (KR)

(72) Inventors: Woong Pyo Hong, Yongin (KR); Hyuk Kang, Yongin (KR); In Woong Lyo, Suwon (KR); Kwang Hoon Choi, Anyang (KR)

(73) Assignee: HYUNDAI MOTOR COMPANY, Seoul (KR)

(21) Appl. No.: 13/830,159

(22) Filed: Mar. 14, 2013

(30) Foreign Application Priority Data
Aug. 29, 2012 (KR) 10-2012-0095122

(51) Int. Cl. C23C 14/34; C23C 14/06

(52) U.S. Cl. CPC C23C 14/3464; C23C 14/0641; C23C 14/345
USPC 428/216; 428/697; 204/192.16

(57) ABSTRACT

Disclosed is a multi-layer coating formed by repeatedly and sequentially laminating first coating layers composed of TiN and second coating layers composed of TiAgN on a surface, and a method of forming the same.

### CROSS-REFERENCE TO RELATED APPLICATION

This application claims under 35 U.S.C. §119(a) the benefit of Korean Patent Application No. 10-2012-0095122 filed Aug. 29, 2012 the entire contents of which are incorporated herein by reference.

### BACKGROUND

(a) Technical Field

The present invention relates to a multi-layer coating and a method for forming the same, particularly a multi-layer coating as a coating material of engine driving parts and the like, which satisfies the requirements of durability, low friction and heat resistance.

(b) Background Art

Diamond-like-carbon (DLC), which is currently used as a coating material for engine driving parts and the like, satisfies durability requirements but does not provide adequate heat resistance. In order to overcome this problem, use of a TiAgN coating material has been suggested. A TiAgN coating material provides low friction and excellent heat resistance.

A TiAgN coating can be produced by using a physical vapor deposition (PVD) device. In particular, a method of injecting nitrogen gas as atmosphere gas on a base material surface under a certain temperature condition, and forming a TiAgN coating layer by forming plasma on the surface using a Ti target and an Ag target is the most reliable production method. A suitable physical vapor deposition (PVD) device and various techniques can be in accordance with, for example, that described in KR10-2010-0001086 A.

However, as Ag content as a soft metal is increased, low friction is improved but hardness is reduced. Therefore, due to its poor durability, it is difficult to commercialize. Further, the required combination of low friction, durability and heat resistance has not been secured to date in a TiAgN coating.

What is needed is a coating material and a coating method that can satisfy all of the necessary durability, heat resistance, and low friction requirements for application as a coating material of engine driving parts and the like.

The description provided above as a related art of the present invention is just for helping understanding the background of the present invention and should not be construed as being included in the related art known by those skilled in the art.

### SUMMARY OF THE DISCLOSURE

The present invention has been made in an effort to solve the above-described problems associated with prior art. The present invention provides a multi-layer coating, which is a TiAgN coating layer, that provides durability and heat resistance, as well as low friction, necessary for its use as coating material of engine driving parts and the like. The present invention further provides a method for forming the multi-layer.

According to one aspect, the present invention provides a multi-coating layer formed by repeatedly and sequentially laminating first coating layers composed of TiN and second coating layers composed of TiAgN.

According to various embodiments, the first coating layer and the second coating layer are each formed to a thickness of about 20˜300 nm.

According to various embodiments, the first coating layer and the second coating layer are repeatedly and sequentially laminated to have about 10˜30 layers in total.

According to various embodiments, the second coating layer comprises Ag in an amount of about 7˜20 at % based on the entire atoms making up the second coating layer.

According to various embodiments, the method for coating the multi-layer coating uses a physical vapor deposition (PVD) device, a Ti target, an Ag target and N₂ gas, comprising: a first coating step of coating the first coating layer composed of TiN on a base material surface by injecting N₂ gas as atmosphere gas and applying current to a Ti target; a second step of coating the second coating layer composed of TiAgN by injecting N₂ gas as atmosphere gas and applying current to both of the Ti target and an Ag target; and a laminating step of repeatedly and sequentially laminating the first coating layer and the second coating layer by repeatedly turning the current applied to the Ag target on (to form TiAgN) and off (to form TiN).

According to various embodiments, the atmosphere gas is N₂ gas or Ar gas.

According to various embodiments, the Ti target is installed at a sputter source unit and the Ag target is installed at an arc source unit to apply current.

According to various embodiments, current of about 1˜2.5 A is applied to the sputter source unit.

According to various embodiments, current of about 50˜200 A is applied to the arc source unit.

According to various embodiments, bias voltage is applied to the base material.

According to various embodiments, the bias voltage is about 100˜250 V.

According to various embodiments, temperature in a chamber of the physical vapor deposition device is about 300˜450° C.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

The above and other features of the invention are discussed infra.

### BRIEF DESCRIPTION OF THE DRAWINGS

The above and other features of the present invention will now be described in detail with reference to certain exemplary embodiments thereof illustrated the accompanying drawings which are given hereinbelow by way of illustration only, and thus are not limitative of the present invention, and wherein:

FIG. 1 is a diagram of the multi-coating layer according to one embodiment of the present invention;

FIG. 2 is an electron microscopic picture enlarging the multi-coating layer illustrated in FIG. 1;

FIGS. 3 and 4 are graphs showing effects according to thickness and the number of layers of the multi-coating layer illustrated in FIG. 1;

FIG. 5 is a flow chart showing the method for coating a multi-layer according to one embodiment of the present invention;

FIGS. 6 and 7 are drawings showing the steps for conducting the method for coating a multi-layer illustrated in FIG. 5;

FIGS. 8 to 10 are graphs showing effects of the method for coating a multi-layer illustrated in FIG. 5; and

FIG. 11 is a graph showing difference in hardness between a TiAgN mono-layer and the multi-coating layer according to one embodiment of the present invention.

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter, the multi-layer coating according preferred embodiments of the present invention, and the method for producing thereof now will be described in detail with reference to the accompanying drawings.

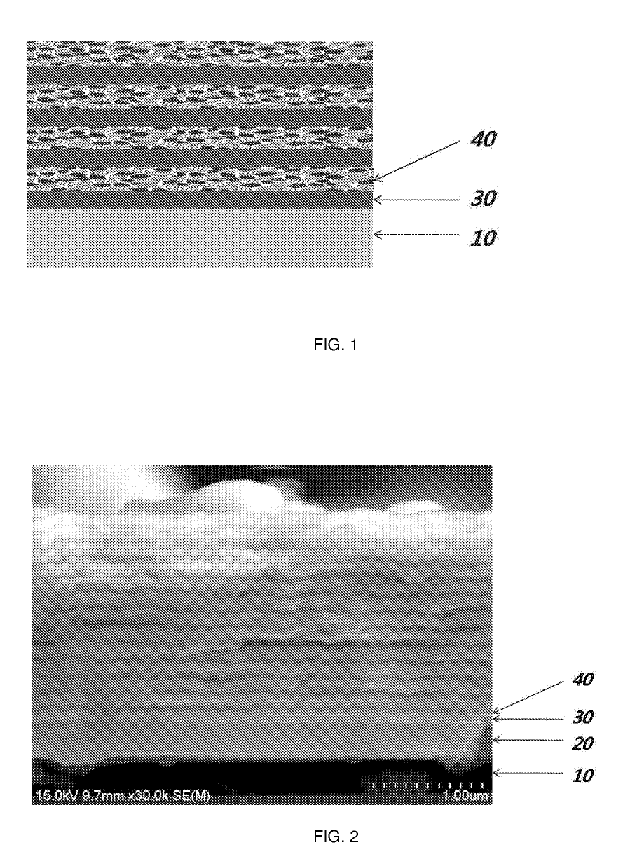

FIG. 1 is a diagram of the multi-coating layer according to one embodiment of the present invention, and FIG. 2 is an electron microscopic picture enlarging the multi-coating layer illustrated in FIG. 1. The multi-coating layer of the present invention is formed by repeatedly and sequentially laminating the first coating layers 30 composed of TiN and the second coating layers 40 composed of TiAgN.

The multi-layer coating can generally be formed by using a PVD device. In particular, the multi-layer coating is formed by laminating TiN and TiAgN sequentially, in contrast with conventional coats of only TiAgN as a mono-layer. As such, the present coatings secure durability and heat resistance as well as required low friction at the same time.

FIG. 2 is an electron microscopic picture enlarging the multi-coating layer illustrated in FIG. 1. As shown, a buffer layer 20 composed of Ti and TiN is formed on the base material 10, and the first coating layers 30 and the second coating layers 40 are laminated in turn thereon. According to a preferred embodiment, a step of forming the buffer layer 20 is accomplished using a Ti implantation process that suitably provides the coating on the base material.

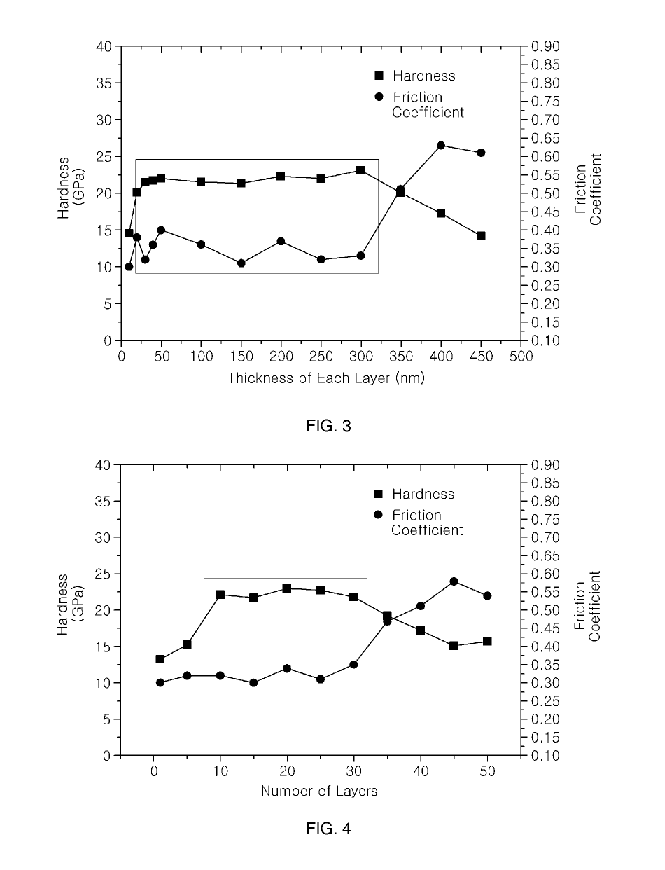

According to preferred embodiments, the first coating layer 30 and the second coating layer 40 are each formed to a thickness of about 20˜300 nm, respectively. FIG. 3 is a graph showing the properties of the multi-layer coating based on the thickness of each of the first and second coating layers 30, 40. In particular, as shown in FIG. 3, both higher hardness and lower friction are demonstrated when the thickness of each coating layer 30, 40 is between about 20 nm and about 300 nm.

Further, it is preferred that the first coating layer 30 and the second coating layer 40 are repeatedly laminated to form a total of about 10˜30 layers. As, shown in FIG. 4, both higher hardness and lower friction are demonstrated when the number of layers is between about 10 layers and about 30 layers.

Further, it is preferred that the second coating layer 40 comprises Ag in an amount of about 7˜20 at % based on the entire atoms making up the second coating layer 40. Such amounts of Ag can be obtained by controlling deposition time of the Ag target and current. When the amount of Ag is at least 7 at %, low friction can be obtained, but when the amount is more than 20 at %, hardness may be lowered.

According to preferred embodiments, the multi-layer coating method for forming the said multi-layer coating uses a physical vapor deposition (PVD) device, a Ti target, an Ag target and N₂ gas. In particular, the method comprises: a first coating step S100 of coating the first coating layer 30 composed of TiN on the base material surface by injecting N₂ gas as atmosphere gas and applying current to a Ti target; a second step S200 of coating the second coating layer 40 composed of TiAgN by injecting N₂ gas as atmosphere gas and applying current to both of the Ti target and an Ag target; and a laminating step S300 of repeatedly laminating the first coating layer 30 and the second coating layer 40 by sequentially turning the current applied to the Ag target OFF (to form a TiN first coating layer 30) and ON (to form a TiAgN second coating layer 40).

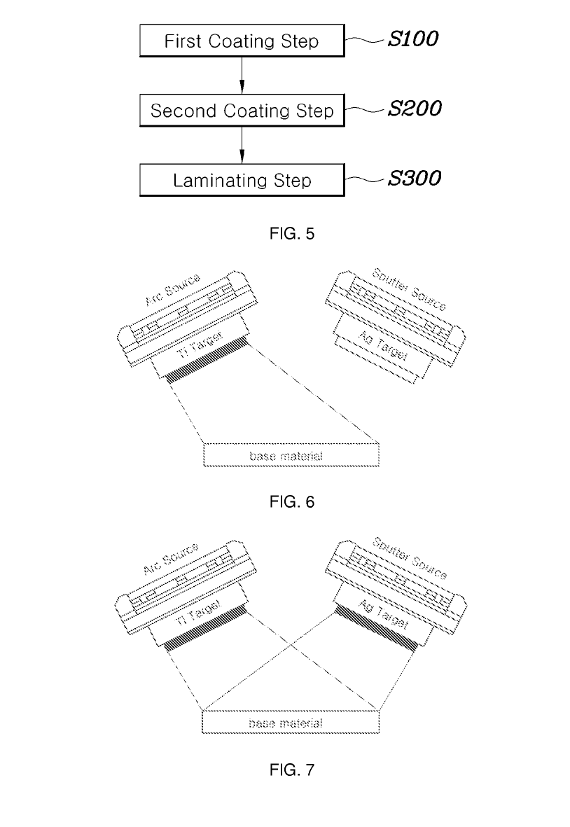

Specifically, FIG. 5 is a flow chart showing the method for coating a multi-layer according to one embodiment of the present invention, and FIGS. 6 and 7 are drawings showing the steps for conducting the method for coating a multi-layer illustrated in FIG. 5. Basically, according to the present method, a TiN layer is formed on the surface of the base material 10 by injecting N₂ gas as atmosphere gas and applying current to the Ti target, then, the TiAgN layer and the TiN layer are sequentially and repeatedly laminated by turning the current applied to the Ag target ON and OFF sequentially and repeatedly, i.e., when ON, the TiAgN layer is coated and when OFF, the TiN layer is coated. The thicknesses of the various layers can be adjusted as desired by varying factors, particularly by varying the timing between ON/OFF of the current applied to the Ag target.

As detailed test conditions, in a vacuum forming step, vacuum is formed in a chamber to minimize the influence of impurities in the atmosphere so as to improve the characteristics of the coating layer. Vacuum pressure formed to about 10⁻³ Torr by using a first rotary pump and then vacuum pressure of 5×10⁻⁵ Torr is maintained by using a second TMP (Turbo Molecular Pump).

As a heating step, in order to induce smooth reaction/binding of nitrogen (N) at high temperatures, the temperature is set to maintain about 300° C. or more and a heat holding time is set to about 40 min or more to make temperature distribution of the surface and inside of the test sample to be coated equal.

As a cleaning step, a test sample is washed by using an ultrasonic washer with ethanol and acetone, and the surface is etched and cleaned in the chamber by using an ion gun for about 20 min or more in order to remove impurities on the surface of the test sample, thereby improving the characteristics of the coating layer.

As a buffer layer forming step, in order to reduce a difference in lattice constant between the base material and the TiAgN layer so as to improve adhesive strength between the coating layer interfaces, Ti can be reacted by an arc ion plating method in nitrogen atmosphere using an arc source to deposit the TiN layer. In particular, a TiN layer can be deposited to a thickness of about 0.1 mm or less.

Then, as a deposition process of the multi-layer coating, in order to repeatedly and sequentially deposit the TiAgN and TiN coating layers 30, 40, Ar gas as atmosphere gas is injected into a coating chamber so as to sputter Ag atoms, and nitrogen (N₂) gas is injected so as to synthesize TiN. At this time, bias voltage is applied to a surfaces to be coated so as to increase deposition efficiency, and the voltage is applied to an arc gun equipped with a Ti target and a sputter gun equipped with an Ag target. Thereafter, an Ag source is turned ON and OFF in sequence so as to sequentially deposit the TiAgN coating layer and the TiN coating layer.

Specifically, the atmosphere gas is N₂ gas or Ar gas so as to deposit the TiN layer and to sputter the Ag atoms.

Further, the Ti target is installed at a sputter source unit, and the Ag target is installed at an arc source unit and then current is applied thereto so as to rapidly produce the layer more effectively and to precisely control the Ti content and the surface.

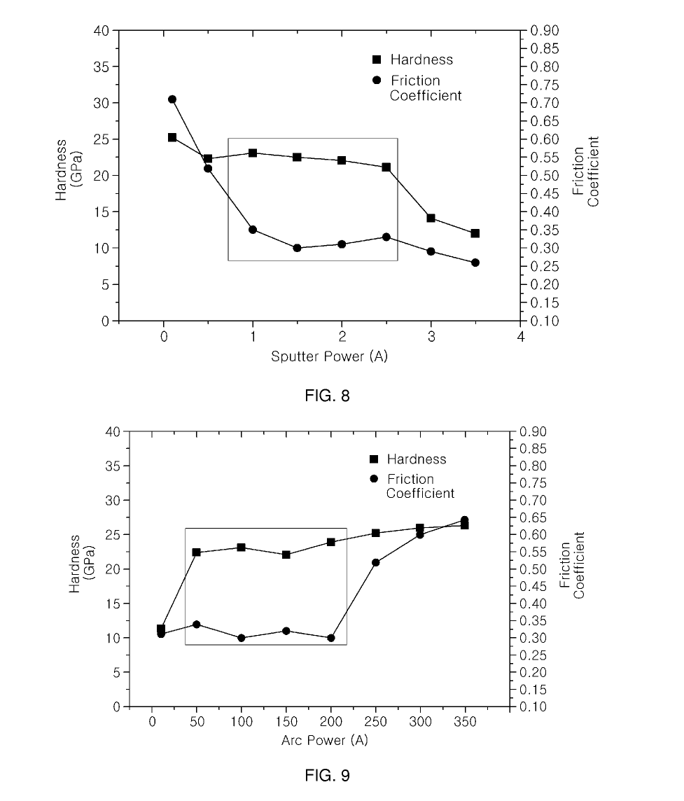

With respect to the sputter source unit, it is preferred to apply current of about 1˜2.5 A. As shown in FIG. 8, when the current of about 1˜2.5 A is applied, the Ti target satisfies both of low friction and high hardness at the same time.

Further, it is preferred to apply current of about 50˜200 A to the arc source unit. As shown in FIG. 9, when the current of about 50˜200 A is applied, the Ag target satisfies both of low friction and high hardness at the same time.

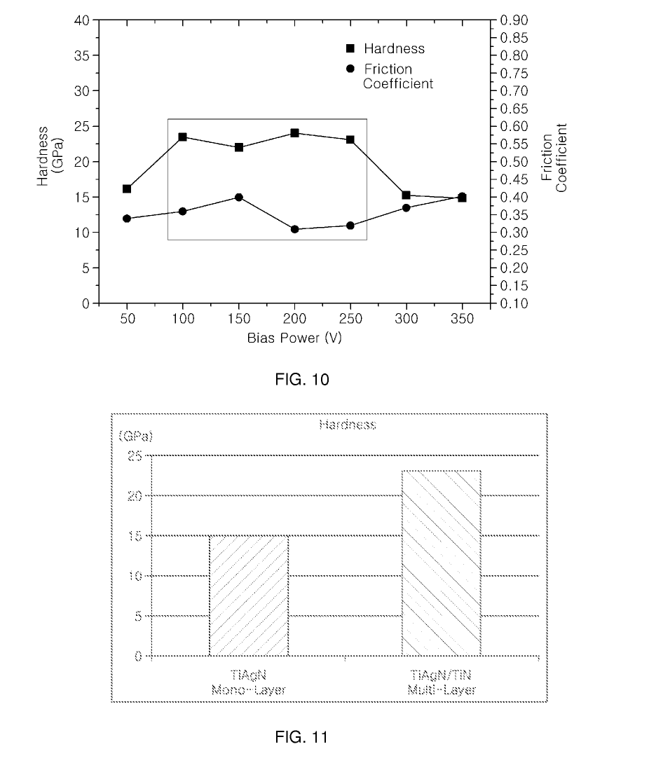

Further, it is preferred that bias voltage is applied to the base material to increase deposition efficiency. According to preferred embodiments, the bias voltage is about 100˜250 V. As shown in FIG. 10, which is a graph showing the results based on bias voltage, when the bias voltage is about 100˜250 V, both of low friction and high hardness can be satisfied at the same time.

According to preferred embodiments, the process temperature in a chamber of the physical vapor deposition device is set to about 300˜450° C. At this temperature, nitrogen reaction/binding proceeds more smoothly, thereby increasing process efficiency and maintaining nitrogen in a proper amount.

In addition, FIG. 11 is a graph showing the difference in hardness between a TiAgN mono-layer and the multi-coating layer according to one embodiment of the present invention. As shown, the multi-coating layer of the present invention has hardness that is improved 40% or more as compared with the previous TiAgN mono-layer coating material. Thus, the present invention provides a multi-layer coating having a very remarkable difference in hardness compared to a conventional coating. Further, the multi-layer coating demonstrates the desired low friction by including therein Ag in a proper amount as described above.

According to the present invention, a multi-coating layer having the constitution described above, and a coating method therefor, provides a hardness that was improved 40% (TiAgN mono-layer: 10˜12 GPa, and coating material of the present invention: 15˜25 GPa) as compared with the conventional TiAgN mono-layer coating material. Further, heat resistance under a high temperature condition of 400° C. or more was improved 30% as compared with the conventional TiAgN mono-layer coating material. Accordingly, the coating material of the present invention can improve fuel efficiency and durability by strengthening durability of engine driving parts and the like by replacing conventional materials such as DLC and the TiAgN mono-layer coating material.

The invention has been described in detail with reference to preferred embodiments thereof. However, it will be appreciated by those skilled in the art that changes or modifications may be made in these embodiments without departing from the principles and spirit of the invention, the scope of which is defined in the appended claims and their equivalents.

What is claimed is:

1. A multi-layer coating comprising a plurality of alternating first coating layers composed of TiN and second coating layers composed of TiAgN.

2. The multi-layer coating according to claim 1, wherein each of the first coating layers and the second coating layers have an individual thickness of about 20˜300 nm.

3. The multi-layer coating according to claim 1, comprising a total of about 10˜30 first coating layers and second coating layers.

4. The multi-coating layer according to claim 1, comprising about 7˜20 at % Ag based on the entire atoms making up the second coating layer.

5. A method of forming a multi-layer coating using a physical vapor deposition (PVD) device, a Ti target, an Ag target and N₂ gas, the method comprising:
a first coating step of coating a first coating layer of TiN on a base material surface by injecting N₂ gas as atmosphere gas and applying current to a Ti target;
a second step of coating a second coating layer of TiAgN on the first coating layer by injecting N₂ gas as atmosphere gas and applying current to both of the Ti target and a Ag target; and
a laminating step of repeatedly and sequentially laminating a plurality of first coating layers and second coating layer by repeatedly turning the current applied to the Ag target OFF and ON.

6. The multi-layer coating method according to claim 5, wherein the atmosphere gas is N₂ gas or Ar gas.

7. The multi-layer coating method according to claim 5, wherein the Ti target is installed at a sputter source unit and the Ag target is installed at an arc source unit to apply current.

8. The multi-layer coating method according to claim 7, wherein a current of about 1˜2.5 A is applied to the sputter source unit.

9. The multi-layer coating method according to claim 7, wherein a current of about 50˜200 A is applied to the arc source unit.

10. The multi-layer coating method according to claim 5, wherein a bias voltage is applied to the base material.

11. The multi-layer coating method according to claim 10, wherein the bias voltage is about 100˜250 V.

12. The multi-layer coating method according to claim 5, wherein a temperature in a chamber of the physical vapor deposition device is about 300˜450° C.
